(19) United States
(12) Patent Application Publication
(10) Pub. No.: US 2026/0239985 A1
(43) Pub. Date: Aug. 13, 2026

(54) SEMICONDUCTOR PACKAGE STRUCTURE

(71) Applicant: MEDIATEK INC., Hsinchu City (TW)

(72) Inventors: Chung-Yuan LIU, Hsinchu City (TW); Ruey-Bo SUN, Hsinchu City (TW); Sheng-Mou LIN, Hsinchu City (TW)

(21) Appl. No.: 19/051,504

(22) Filed: Feb. 12, 2025

(51) Int. Cl. H01L 23/58; H01L 23/00; H01L 23/31; H01L 23/538; H01L 25/18; H10D 1/20

(52) U.S. Cl. CPC H10W 42/00; H10W 70/611; H10W 90/00; H10W 90/401; H10D 1/20; H10W 74/121; H10W 90/722; H10W 90/724

(57) ABSTRACT

A semiconductor package structure includes a first semiconductor die, a second semiconductor die, and a conductive structure. The first semiconductor die includes a electrical component and an inductor disposed in a dielectric layer. The first semiconductor die also includes a semiconductor substrate disposed over the dielectric layer. The first semiconductor die also includes a first row of guarding-through vias extending through the semiconductor substrate and between the electrical component and the inductor. The second semiconductor die vertically overlaps the first row of through vias. The conductive structure is disposed over the first semiconductor die and electrically couples the second semiconductor die to the first row of guarding-through vias.

### BACKGROUND OF THE INVENTION

### Field of the Invention

The present invention relates in general to semiconductor technology, and, in particular, it relates to a semiconductor package structure.

### Description of the Related Art

In addition to providing a semiconductor die with protection from environmental contaminants, a semiconductor package structure can also provide an electrical connection between the semiconductor die packaged inside it and a substrate such as a printed circuit board (PCB). With the trend of miniaturization of electronic products, it is necessary to continuously reduce the size of semiconductor package structures. Stacked-die technology is a mainstream of modern advanced semiconductor package structures due to its smaller form factor and higher integration.

Although existing semiconductor package structures generally meet requirements, they have not been satisfactory in all respects. For example, parallel conductive layers of stacked dies may make an enhanced inductor-to-inductor coupling level. This may result in a fatal coupling spur. Therefore, further improvements in semiconductor package structures are required.

### BRIEF SUMMARY OF THE INVENTION

Semiconductor package structures are provided. An exemplary embodiment of a semiconductor package structure includes a first semiconductor die, a second semiconductor die, and a conductive structure. The first semiconductor die includes an electrical component and an inductor disposed in a dielectric layer. The first semiconductor die also includes a semiconductor substrate disposed over the dielectric layer. The first semiconductor die also includes a first row of guarding-through vias extending through the semiconductor substrate and between the electrical component and the inductor. The second semiconductor die vertically overlaps the first row of through vias. The conductive structure is disposed over the first semiconductor die and electrically couples the second semiconductor die to the first row of guarding-through vias.

Another embodiment of a semiconductor package structure includes a first semiconductor die and a second semiconductor die. The first semiconductor die includes an electrical component and an inductor disposed on a frontside of the first semiconductor die. The first semiconductor die also includes a conductive layer between the electrical component and the inductor. The first semiconductor die also includes a plurality of guarding-through vias extending from a backside of the first semiconductor die to the conductive layer and arranged along a first sidewall of the inductor. The second semiconductor die is disposed over the backside of the first semiconductor die and is electrically coupled to the guarding-through vias.

Yet another embodiment of a semiconductor package structure includes a first semiconductor die and a second semiconductor die. The first semiconductor die includes an electrical component and an inductor adjacent to the electrical component. The first semiconductor die also includes a plurality of first guarding-through vias surrounding the electrical component. A first side of the first guarding-through vias is electrically coupled to a ground. The second semiconductor die is disposed over the first semiconductor die and includes a conductive layer. The conductive layer is electrically coupled to a second side of the first guarding-through vias.

### BRIEF DESCRIPTION OF THE DRAWINGS

The present invention can be more fully understood by reading the subsequent detailed description and examples with references made to the accompanying drawings, wherein:

FIG. 1A is a cross-sectional view of an exemplary semiconductor package structure in accordance with some embodiments of the present disclosure;

FIG. 1B is a cross-sectional view of an exemplary semiconductor package structure in accordance with some embodiments of the present disclosure;

FIG. 2 is a cross-sectional view of an exemplary semiconductor package structure in accordance with some embodiments of the present disclosure;

FIG. 3 is a cross-sectional view of an exemplary semiconductor die in accordance with some embodiments of the present disclosure;

FIG. 4 is a perspective view of an exemplary semiconductor die in accordance with some embodiments of the present disclosure;

FIG. 5 is a top view of an exemplary semiconductor die in accordance with some embodiments of the present disclosure;

FIG. 6 is a top view of an exemplary semiconductor die in accordance with some embodiments of the present disclosure;

FIG. 7 is a top view of an exemplary semiconductor die in accordance with some embodiments of the present disclosure;

FIG. 8 is a perspective view of an exemplary semiconductor die in accordance with some embodiments of the present disclosure;

FIG. 9 is a perspective view of an exemplary semiconductor die in accordance with some embodiments of the present disclosure;

FIG. 10 is a perspective view of an exemplary semiconductor die in accordance with some embodiments of the present disclosure;

FIG. 11 is a cross-sectional view of an exemplary semiconductor package structure in accordance with some embodiments of the present disclosure;

FIG. 12 is a cross-sectional view of an exemplary semiconductor package structure in accordance with some embodiments of the present disclosure; and

FIG. 13 is a cross-sectional view of an exemplary semiconductor package structure in accordance with some embodiments of the present disclosure.

### DETAILED DESCRIPTION OF THE INVENTION

The following description is made for the purpose of illustrating the general principles of the invention and should not be taken in a limiting sense. The scope of the invention is best determined by reference to the appended claims.

The present disclosure will be described with respect to particular embodiments and with reference to certain drawings, but the disclosure is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the disclosure.

Additional elements may be added on the basis of the embodiments described below. For example, the description of “a first element on/over a second element” may include embodiments in which the first element is in direct contact with the second element, and may also include embodiments in which additional elements are disposed between the first element and the second element such that the first element and the second element are not in direct contact.

Furthermore, the description of “a first element extending through a second element” may include embodiments in which the first element is disposed in the second element and extends from a side of the second element to an opposite side of the second element, wherein a surface of the first element may be substantially leveled with a surface of the second element, or a surface of the first element may be outside a surface of the second element.

The spatially relative descriptors of the first element and the second element may change as the structure is operated or used in different orientations. In addition, the present disclosure may repeat reference numerals and/or letters in the various embodiments. This repetition is for simplicity and clarity and does not in itself dictate a relationship between the various embodiments discussed. For avoidance of doubts, the X direction, the Y direction, and the Z direction in the figures are perpendicular to one another and are used consistently.

A semiconductor package structure including inductors and guarding-through vias between the inductors is described in accordance with some embodiments of the present disclosure. Therefore, the guarding-through vias form isolation cages for the inductors, so that coupling issue due to conductive layers of stacked semiconductor dies can be alleviated.

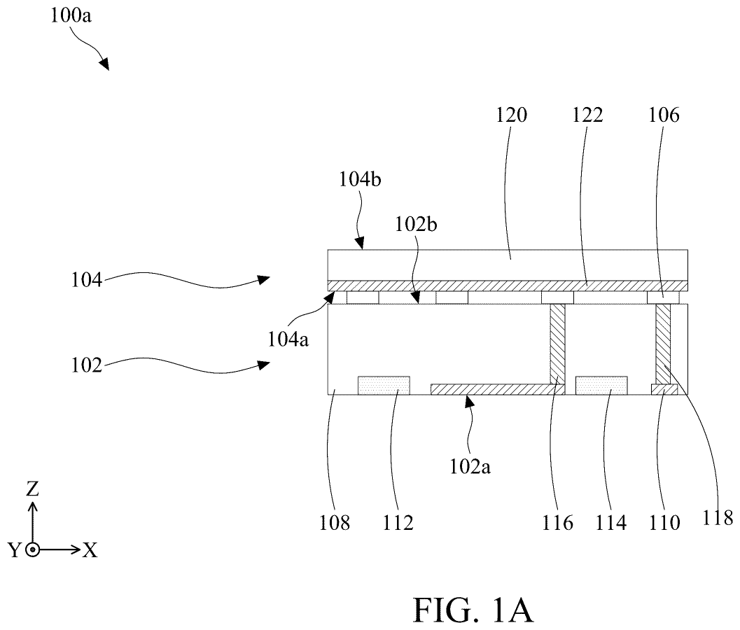

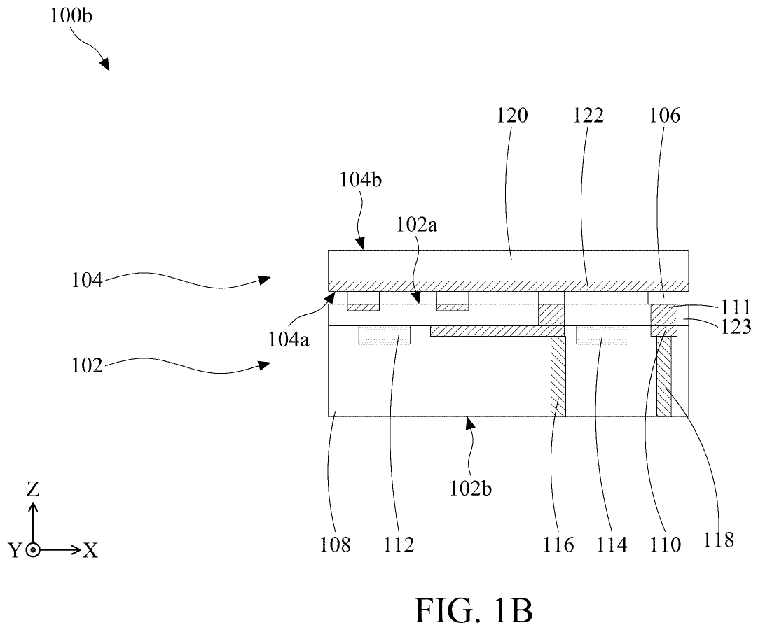

FIG. 1A is a cross-sectional view of a semiconductor package structure 100a in accordance with some embodiments of the present disclosure. Additional features can be added to the semiconductor package structure 100a. Some of the features described below can be replaced or eliminated for different embodiments. To simplify the diagram, only a portion of the semiconductor package structure 100a is illustrated.

As illustrated in FIG. 1, the semiconductor package structure 100a includes a first semiconductor die 102 and a second semiconductor die 104, in accordance with some embodiments. The first semiconductor die 102 and the second semiconductor die 104 may be stacked vertically, such as in the Z direction.

In some embodiments, the first semiconductor die 102 and the second semiconductor die 104 each independently includes a system-on-chip (SoC) die, a logic device, a memory device, a radio frequency (RF) device, the like, or a combination thereof. For example, the first semiconductor die 102 and the second semiconductor die 104 may each independently include a micro control unit (MCU) die, a microprocessor unit (MPU) die, a power management integrated circuit (PMIC) die, a radio frequency front end (RFFE) die, an accelerated processing unit (APU) die, a central processing unit (CPU) die, a graphics processing unit (GPU) die, an input-output (IO) die, a dynamic random access memory (DRAM) controller, a static random-access memory (SRAM), a high bandwidth memory (HBM), an application processor (AP) die, an application specific integrated circuit (ASIC) die, the like, or a combination thereof. The first semiconductor die 102 and the second semiconductor die 104 may include the same die or different dies.

The first semiconductor die 102 may be electrically coupled to the second semiconductor die 104 through a plurality of conductive connectors 106. The conductive connectors 106 may include bump structure or another suitable structures. For example, the conductive connectors 106 may include microbumps, controlled collapse chip connection (C4) bumps, conductive pillars, solder paste, ball grid array (BGA) balls, the like, or a combination thereof. The conductive connectors 106 may be formed of metal, including tungsten, titanium, tantalum, ruthenium, cobalt, copper, aluminum, platinum, tin, silver, gold, the like, an alloy thereof, or a combination thereof.

The first semiconductor die 102 may have a frontside surface 102a and a backside surface 102b opposite the frontside surface 102a. The first semiconductor die 102 includes a semiconductor substrate 108, in accordance with some embodiments. The semiconductor substrate 108 may include a bulk semiconductor, a compound semiconductor, an alloy semiconductor, the like, or a combination thereof. The semiconductor substrate 108 may be formed of any suitable semiconductor material, including silicon, germanium, the like, or a combination thereof. The semiconductor substrate 108 may be doped (e.g., using p-type or n-type dopants) or undoped. For example, the p-type dopants may include boron, and the n-type dopants may include phosphorus or arsenic.

The first semiconductor die 102 includes one or more conductive layers 110 on the frontside surface 102a, in accordance with some embodiments. The conductive layers 110 may be formed of metal, including tungsten, titanium, tantalum, ruthenium, cobalt, copper, aluminum, platinum, tin, silver, gold, the like, an alloy thereof, or a combination thereof.

The first semiconductor die 102 includes an electrical component 112 and an inductor 114 adjacent to the electrical component 112, in accordance with some embodiments. For example, the electrical component 112 may have high speed or high power circuit. For example, the electrical component 112 and the inductor 114 may include an inductor-capacitor phase-locked loops (LC-PLLs). The electrical component 112 may be an aggressor on-die inductor, and the inductor 114 may be a victim on-die inductor.

The second semiconductor die 104 may have a frontside surface 104a and a backside surface 104b opposite the frontside surface 104a. The second semiconductor die 104 includes a semiconductor substrate 120, in accordance with some embodiments. The semiconductor substrate 120 may include a bulk semiconductor, a compound semiconductor, an alloy semiconductor, the like, or a combination thereof. The semiconductor substrate 120 may be formed of any suitable semiconductor material, including silicon, germanium, the like, or a combination thereof. The semiconductor substrate 120 may be doped (e.g., using p-type or n-type dopants) or undoped. For example, the p-type dopants may include boron, and the n-type dopants may include phosphorus or arsenic.

The second semiconductor die 104 includes one or more conductive layers 122 on the frontside surface 104a, in accordance with some embodiments. The conductive layers 122 may be formed of metal, including tungsten, titanium, tantalum, ruthenium, cobalt, copper, aluminum, platinum, tin, silver, gold, the like, an alloy thereof, or a combination thereof.

The second semiconductor die 104 may at least partially overlap the area between the first electrical component 112 and the inductor 114. In particular, the conductive layers 122 in the second semiconductor die 104 may at least partially overlap the area between the first electrical component 112 and the inductor 114.

When the first semiconductor die 102 including the first electrical component 112 and the inductor 114 is stacked with the second semiconductor die 104, the conductive layer 110 of the first semiconductor die 102 and the conductive layer 122 of the second semiconductor die 104 form a strong coupling path, which can be regarded as a parallel plate waveguide. This coupling path makes an enhanced inductor-to-inductor coupling level, and results in fatal coupling spur issue for the inductors in the first semiconductor die 102.

To resolve this coupling issue due to the conductive layers 110 and 122 of the stacked dies, a plurality of guarding-through vias 116 and 118 are formed in the first semiconductor die 102, in accordance with some embodiments. A projection of the guarding-through vias 116 on the bottom surface of the first semiconductor die 102 may be disposed between the electrical component 112 and the inductor 114. The guarding-through vias 116 and 118 may each be independently formed of conductive materials, such as metal, including copper, aluminum, nickel, gold, silver, the like, an alloy thereof, or a combination thereof.

The guarding-through vias 116 and 118 may surround at least one of the inductors, such as the inductor 114. Although the following descriptions are based on the guarding-through vias 116 and 118 surrounding the inductor 114, it should be understood that the guarding-through vias 116 and 118 may surround the electrical component 112 instead.

The guarding-through vias 116 and 118 may extend through the semiconductor substrate 108. In particular, the guarding-through vias 116 and 118 may extend from the backside surface 102b of the first semiconductor die 102 to the conductive layer 110. The guarding-through vias 116 and 118 may be electrically coupled to ground potential, with one side electrically coupled to the conductive layer 110 in the first semiconductor die 102, and the other side electrically coupled to the conductive connectors 106, which may be electrically coupled to ground potential of the conductive layer 122 of the second semiconductor die 104. In some embodiments, the guarding-through vias 116 and 118 are electrically coupled to the analog ground potential. As a result, the guarding-through vias 116 and 118 can form isolation cages for all the electrical component 112 and inductor 114 to reduce coupling.

In addition, since there is no need to increase the distance between the inductors 112 and 114 or increase the distance between the first semiconductor die 102 and the second semiconductor die 104 for coupling suppression, the volume of the semiconductor package structure 100 can be reduced, and the cost can be reduced.

It should be noted that the electrical component 112 and the inductor 114 are for illustrative purposes only, and more inductors may be disposed in the first semiconductor die 102. The first semiconductor die 102 may include one or more active and passive devices (not shown). For example, the active and passive devices may include transistors, capacitors, resistors, the like, or a combination thereof.

FIG. 1B is a cross-sectional view of a semiconductor package structure 100b in accordance with some embodiments of the present disclosure. Additional features can be added to the semiconductor package structure 100b. Some of the features described below can be replaced or eliminated for different embodiments. To simplify the diagram, only a portion of the semiconductor package structure 100b is illustrated.

The semiconductor structure 100b of FIG. 1B includes elements that are similar to, or the same as, elements of the semiconductor structure 100a of FIG. 1A, the difference between FIG. 1B and FIG. 1A is that the frontside surface 102a of the first semiconductor die 102 faces the frontside surface 104a of the second semiconductor die 104 in FIG. 1B. In other words, the semiconductor structure 100a includes a face-to face stacked die structure.

As shown in FIG. 1B, the first semiconductor die 102 may be electrically coupled to the second semiconductor die 104 through a plurality of conductive connectors 106. The first semiconductor die 102 includes the electrical component 112 and the inductor 114 and the guarding-through vias 116 and 118. The guarding-through vias 116 and 118 surround at least one of the inductors, such as the inductor 114. The second semiconductor die 104 includes the semiconductor substrate 120 and one or more conductive layers 122. In some embodiments, the conductive layer 110 is electrically connected to the conductive layer 122 of the second semiconductor die 104 by the conductive pads 111 in a passivation layer 123. The guarding-through vias 116 and 118 can form isolation cages for all the electrical component 112 and inductor 114 to reduce coupling.

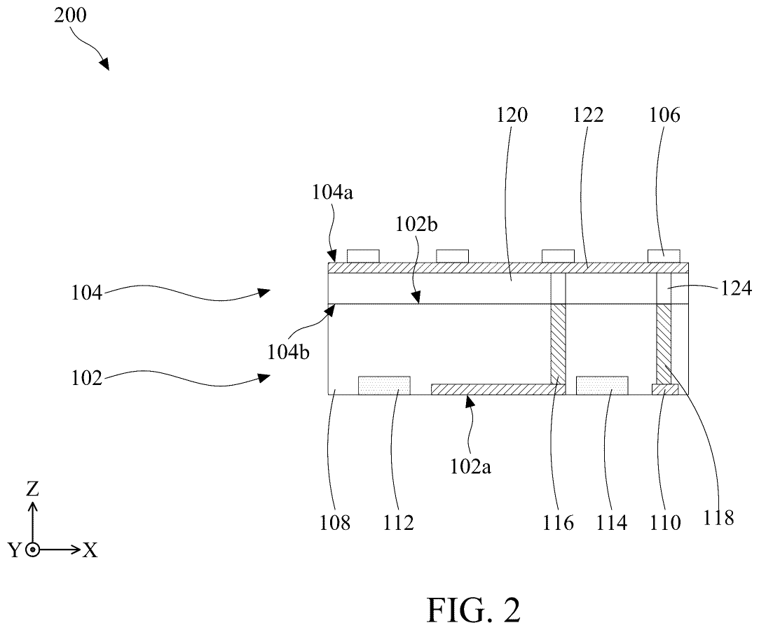

FIG. 2 is a cross-sectional view of a semiconductor package structure 200 in accordance with some embodiments of the present disclosure. It should be noted that the semiconductor package structure 200 may include the same or similar components as those of the semiconductor package structure 100, which is illustrated in FIG. 1, and for the sake of simplicity, those components will not be discussed in detail again. In the following embodiments, the first semiconductor die 102 and the second semiconductor die 104 are stacked back to back.

As illustrated in FIG. 2, the backside surface 102b of the first semiconductor die 102 is adjacent to the backside surface 104b of the second semiconductor die 104. In some embodiments, the first semiconductor die 102 and the second semiconductor die 104 may be bonded using fusion bonding, hybrid bonding, or another suitable methods. Fusion bonding may include dielectric-to-dielectric bonding and/or conductor-to-conductor bonding. Hybrid bonding may be a combination of dielectric-to-dielectric bonding and conductor-to-conductor bonding, which may be metal-to-metal direct bonding, such as copper-to-copper direct bonding.

In some other embodiment, the first semiconductor die 102 and the second semiconductor die 104 may be bonded using an adhesive layer (not illustrated). The adhesive layer may include a die attach film or another suitable materials.

The second semiconductor die 104 includes a plurality of through vias 124 in the semiconductor substrate 120, in accordance with some embodiments. The through vias 124 may be formed of conductive material, such as metal including copper, aluminum, nickel, gold, silver, the like, an alloy thereof, or a combination thereof.

The through vias 124 may extend through the semiconductor substrate 120. In particular, the through vias 120 may extend from the backside surface 104b of the second semiconductor die 104 to the conductive layer 122. The guarding-through vias 116 and 118 may be electrically coupled to the conductive layers 122 through the through vias 124.

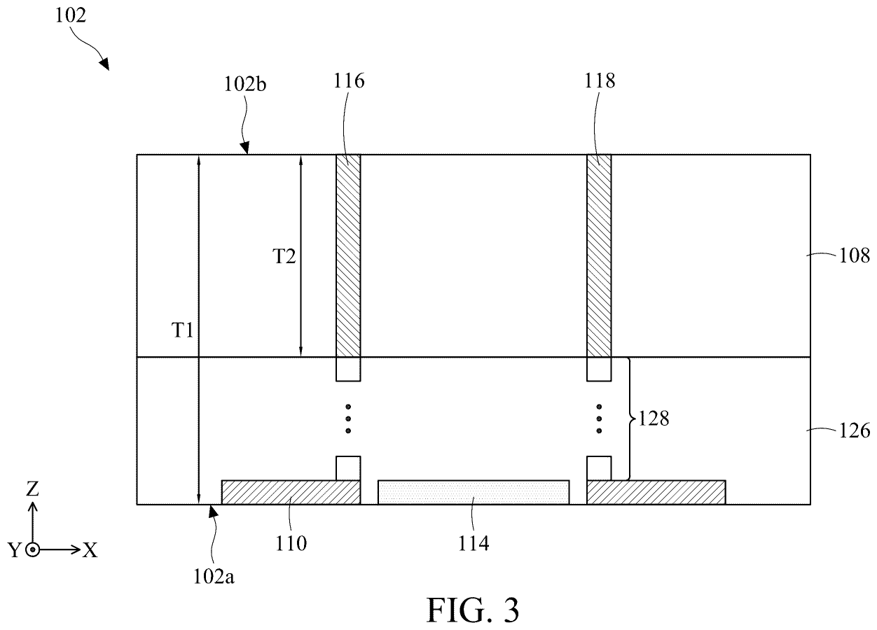

FIG. 3 is a cross-sectional view of a portion of the first semiconductor die 102 of the semiconductor package structure 100 illustrated in FIG. 1 or the semiconductor package structure 200 illustrated in FIG. 2 in accordance with some embodiments of the present disclosure. The first semiconductor die 102 is described in more detail in the following embodiments.

As illustrated in FIG. 3, the first semiconductor die 102 includes a dielectric layer 126 below the semiconductor substrate 108, in accordance with some embodiments. The conductive layers 110 and the inductor 114 may be disposed in the dielectric layer 126. The dielectric layer 126 may be formed of organic materials, such as a polymer base material, non-organic materials, including silicon nitride, silicon oxide, silicon oxynitride, the like, or a combination thereof.

The first semiconductor die 102 includes routing layers 128 in the dielectric layer 126, in accordance with some embodiments. The routing layers 128 may include horizontal interconnects, such as conductive layers or conductive pads, and vertical interconnects, such as conductive vias. The conductive vias may electrically couple different levels of the conductive layers to the conductive pads.

The routing layers 128 may be electrically coupled the conductive layers 110, and the guarding-through vias 116 and 118 may be electrically coupled the conductive layers 110 through the routing layers 128. The routing layers 128 may be formed of a material similar to that of the conductive layers 110, such as metal, including tungsten, titanium, tantalum, ruthenium, cobalt, copper, aluminum, platinum, tin, silver, gold, the like, an alloy thereof, or a combination thereof.

The first semiconductor die 102 may have a thickness T1, which may be substantially equal to the distance between the frontside surface 102a and the backside surface 102b. The thickness T1 of the first semiconductor die 102 may be substantially equal to or larger than 10 μm. For example, the thickness T1 of the first semiconductor die 102 may be in a range of about 10 μm to about 500 μm.

Each of the guarding-through vias 116 and 118 may have a thickness T2, which may be substantially equal to the thickness of the semiconductor substrate 108.

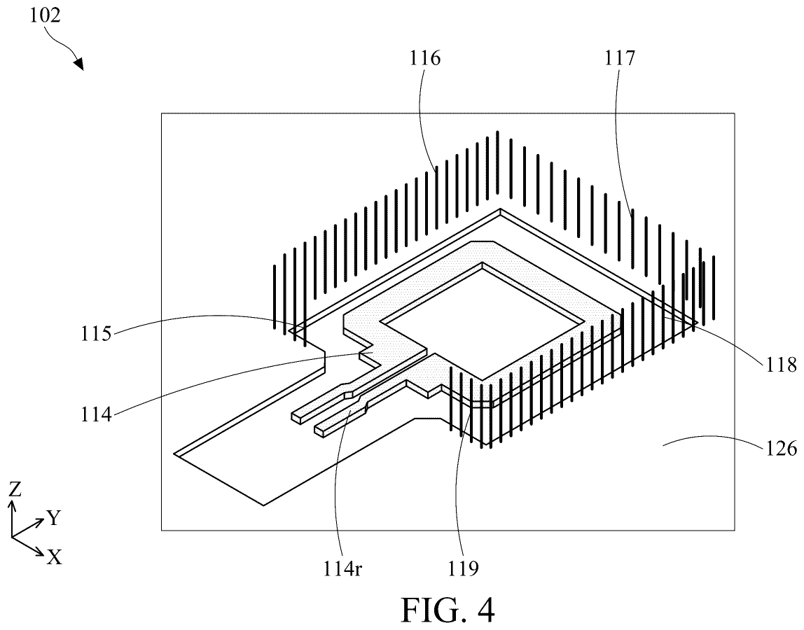

FIG. 4 is a perspective view of a portion of the semiconductor die 102 of the semiconductor package structure 100 illustrated in FIG. 1 or the semiconductor package structure 200 illustrated in FIG. 2 in accordance with some embodiments of the present disclosure. The first semiconductor die 102 will be described in more detail in the following

### Embodiments.

As illustrated in FIG. 4, the first semiconductor die 102 includes a plurality of guarding-through vias 115, 116, 117, 118, and 119, in accordance with some embodiments. The guarding-through vias 115, 116, 117, 118, and 119 may be disposed over the dielectric layer 126. The guarding-through vias 115, 117, and 119 may be formed of the material similar to that of the guarding-through vias 116 and 118 as discussed above, and will not be repeated.

The guarding-through vias 116 may be arranged in a row along a first sidewall of the inductor 114. The guarding-through vias 117 may be arranged in a row along a second sidewall of the inductor 114. The guarding-through vias 118 may be arranged in a row along a third sidewall of the inductor 114. The guarding-through vias 115 and 119 may be arranged in a row along a fourth sidewall of the inductor 114. As a result, the inductor 114 may be surrounded by the guarding-through vias 115, 116, 117, 118, and 119.

The guarding-through vias 115, 116, 117, 118, and 119 may be electrically coupled to ground potential, with one side electrically coupled to the conductive layers 110 in the first semiconductor die 102, and the other side electrically coupled to the conductive connectors 106 (as illustrated in FIG. 1 or 2), which may be electrically coupled to ground potential of the conductive layers 122 of the second semiconductor die 104. As a result, the guarding-through vias 115, 116, 117, 118, and 119 can form isolation cages for the electrical component 112 and the inductor 114 to reduce coupling.

The inductor 114 may have conductive layers 114r. The conductive layers 114r may extend in a direction different from the arrangement direction of the guarding-through vias 115 and the guarding-through vias 119. For example, the guarding-through vias 115 and the guarding-through vias 119 may be arranged in the X direction, and the conductive layers 114r may extend in the Y direction. The conductive layers 114r may separate the guarding-through vias 115 from the guarding-through vias 119.

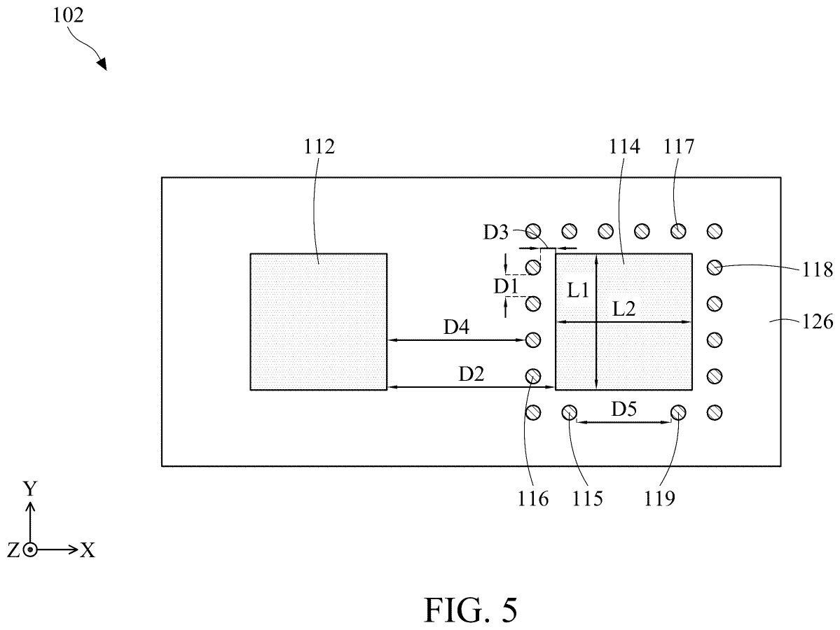

FIG. 5 is a top view of the semiconductor die 102 of the semiconductor package structure 100 illustrated in FIG. 1 or the semiconductor package structure 200 illustrated in FIG. 2 in accordance with some embodiments of the present disclosure. To simplify the diagram, the numbers of the guarding-through vias 115, 116, 117, 118, and 119 are further reduced. The first semiconductor die 102 is described in more detail in the following embodiments.

As illustrated in FIG. 5, the inductor 114 may have dimensions (such as width and length) L1 and L2. Adjacent two of the guarding-through vias 115, 116, 117, 118, and 119 may be separated by a distance D1. The distance D1 may be less than the dimension L1 and less than the dimension L2 of the inductor 114. The distance D1 may be less than 500 um, such as 50 um (depends on working frequency). If the distance D1 is too large, electromagnetic field can easily pass through the gap between guarding-through vias 115, 116, 117, 118, and 119 and thus fail to reduce crosstalk.

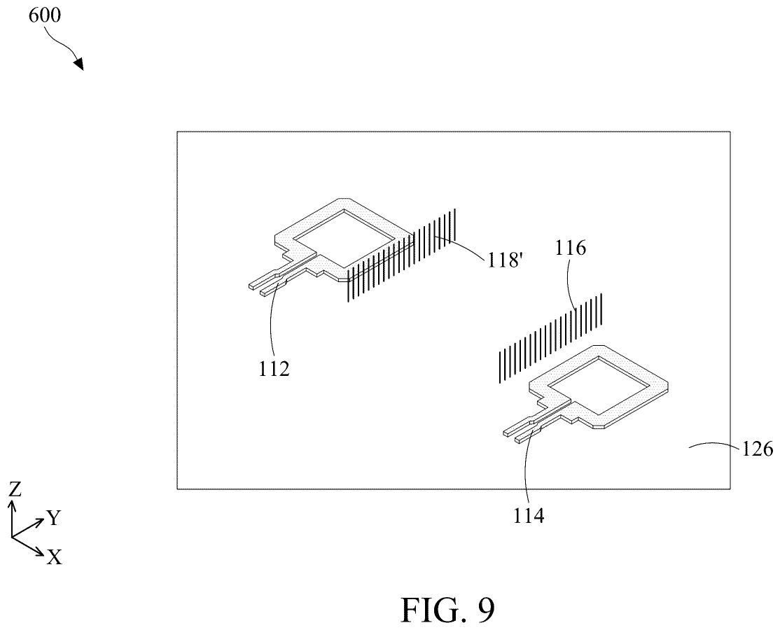

The inductor 114 may be spaced apart from the electrical component 112 by a distance D2. The guarding-through vias 115, 116, 117, 118, and 119 may be separated from the inductor 114 by a distance D3. The distance D3 may be less than the distance D2 between the electrical component 112 and the inductor 114. The distance D3 may be larger than 0.5 um, such as 5 um (depends on working frequency). If the distance D3 is too small, the inductance of the inductor will be hugely degraded and failed to be functional. If guarding-through vias 115, 116, 117, 118, and 119 surrounds inductor as shown in FIG. 5, the distance D3 has no maximum limit. If guarding-through vias 115, 116, 117, 118, and 119 are only placed in specific border of inductor (as shown in FIGS. 9 & 10), the distance D3 may be less than 500 um.

A minimum distance between the electrical component 112 and the guarding-through vias 115, 116, 117, 118, and 119 may be the distance D4 between the guarding-through vias 116 and the electrical component 112. The distance D4 may be greater than the distance D3.

The guarding-through vias 115 may be separated from the guarding-through vias 119 by a distance D5. The distance D5 may be greater than the distance D1. The distance D5 may be less than the dimension L1 and less than the dimension L2 of the inductor 114.

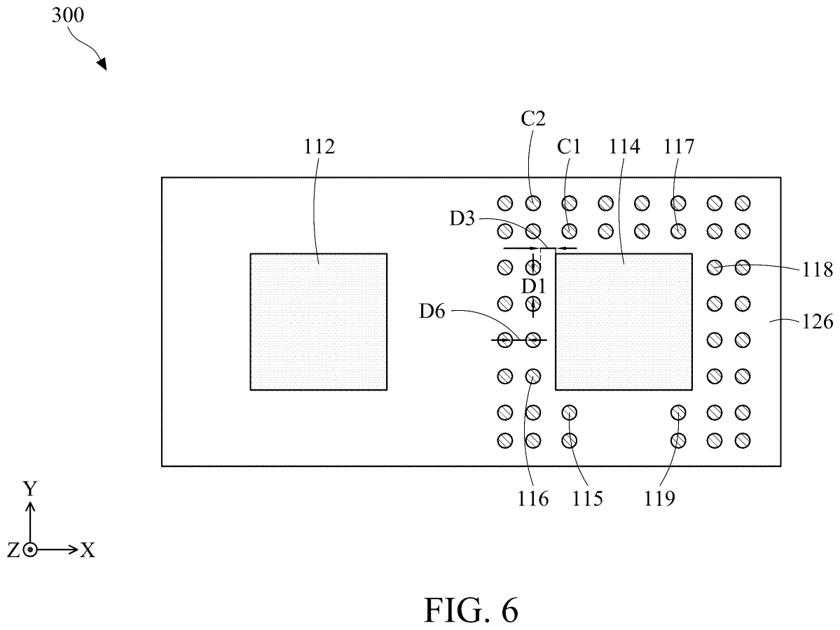

FIG. 6 is a top view of a semiconductor die 300 in accordance with some embodiments of the present disclosure. It should be noted that the semiconductor die 300 may include the same or similar components as those of the semiconductor die 102, which is illustrated in FIG. 5, and for the sake of simplicity, those components will not be discussed in detail again. In the following embodiments, more than one circle of guarding-through vias 115, 116, 117, 118, 119 surround the inductor 114.

As illustrated in FIG. 6, first rows of the through vias 115, 116, 117, 118, 119 form a first circle C1, and second rows of the through vias 115, 116, 117, 118, 119 form a second circle C2. It should be noted that two circles are for illustrative purposes only, and the through vias 115, 116, 117, 118, 119 may be arranged in more than two circles. By increasing the number of circles, the coupling issue can be further reduced.

The through vias 115, 116, 117, 118, 119 of the first circle C1 may be substantially aligned with the through vias 115, 116, 117, 118, 119 of the second circle C2, respectively. In particular, the through vias 115, 116, 117, 118, 119 of the first circle C1 and the through vias 115, 116, 117, 118, 119 of the second circle C2 are in an aligned arrangement (or in an in-line arrangement).

The through vias 115, 116, 117, 118, 119 of the first circle C1 may be spaced apart from the through vias 115, 116, 117, 118, 119 of the second circle C2 by a distance D6. A distance D1 between adjacent two of the guarding-through vias 115, 116, 117, 118, 119 of the first circle C1 may be substantially equal to a distance between adjacent two of the guarding-through vias 115, 116, 117, 118, 119 of the second circle C2. The distance D6 may be greater than, substantially equal to, or less than the distance D1. The distance D6 may be in a range of about 10 μm to about 500 μm.

The guarding-through vias 115, 116, 117, 118, 119 of the first circle C1 may be separated from the inductor 114 by the distance D3. The distance D3 may be greater than, substantially equal to, or less than the distance D6.

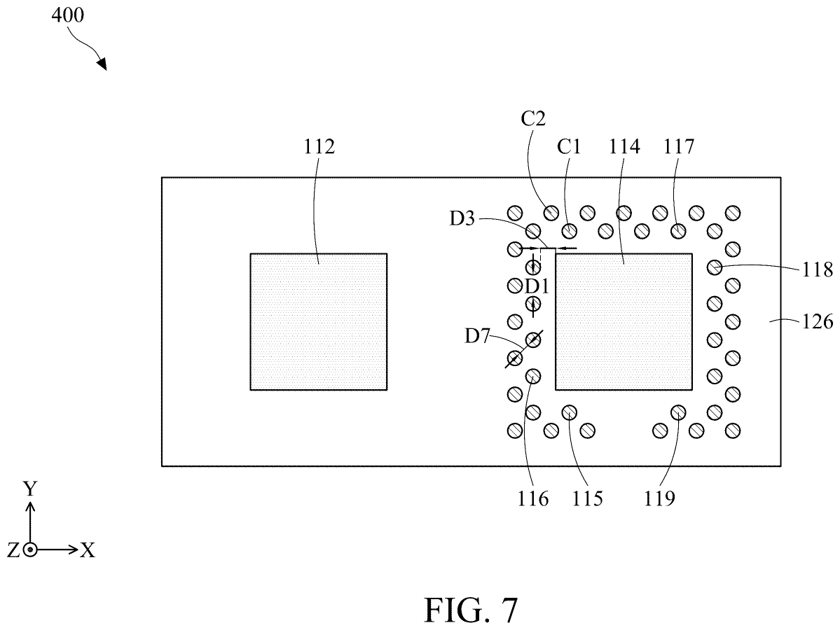

FIG. 7 is a top view of a semiconductor die 400 in accordance with some embodiments of the present disclosure. It should be noted that the semiconductor die 400 may include the same or similar components as those of the semiconductor die 300, which is illustrated in FIG. 6, and for the sake of simplicity, those components will not be discussed in detail again. In the following embodiments, the guarding-through vias 115, 116, 117, 118, 119 of different circles are in a staggered arrangement.

As illustrated in FIG. 7, first rows of the through vias 115, 116, 117, 118, 119 form a first circle C1, and second rows of the through vias 115, 116, 117, 118, 119 form a second circle C2. It should be noted that two circles are for illustrative purposes only, and the through vias 115, 116, 117, 118, 119 may be arranged in more than two circles. By increasing the number of circles, the coupling issue can be further reduced.

The through vias 115, 116, 117, 118, 119 of the first circle C1 and the through vias 115, 116, 117, 118, 119 of the second circle C2 may be staggered, respectively. In comparison with the aligned arrangement (or in-line arrangement) in FIG. 6, the staggered arrangement in FIG. 7 can further reduce the coupling issue.

The through vias 115, 116, 117, 118, 119 of the first circle C1 may be spaced apart from the through vias 115, 116, 117, 118, 119 of the second circle C2 by a distance D7. A distance D1 between adjacent two of the guarding-through vias 115, 116, 117, 118, 119 of the first circle C1 may be substantially equal to a distance between adjacent two of the guarding-through vias 115, 116, 117, 118, 119 of the second circle C2. The distance D7 may be greater than, substantially equal to, or less than the distance D1. The distance D7 may be in a range of about 10 μm to about 500 μm.

The guarding-through vias 115, 116, 117, 118, 119 of the first circle C1 may be separated from the inductor 114 by the distance D3. The distance D3 may be greater than, substantially equal to, or less than the distance D7.

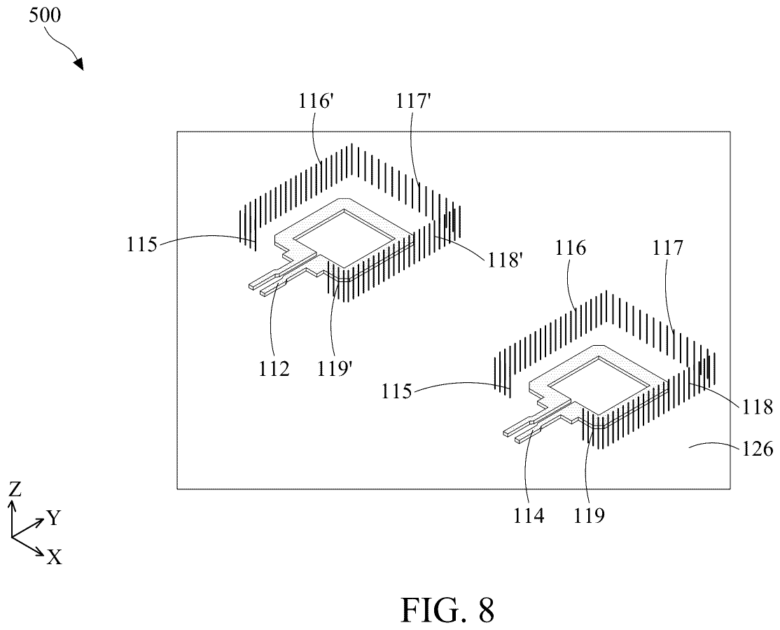

FIG. 8 is a perspective view of a semiconductor die 500 in accordance with some embodiments of the present disclosure. It should be noted that the semiconductor die 500 may include the same or similar components as those of the semiconductor die 102, which is illustrated in FIG. 4, and for the sake of simplicity, those components will not be discussed in detail again. In the following embodiments, the guarding-through vias surround both of the electrical component 112 and the inductor 114.

As illustrated in FIG. 8, the semiconductor die 500 includes guarding-through vias 115, 116, 117, 118, 119 around the inductor 114 and guarding-through vias 115′, 116′, 117′, 118′, 119′ around the electrical component 112, in accordance with some embodiments. The material and the arrangement of the guarding-through vias 115′, 116′, 117′, 118′, and 119′ may be similar to those of the guarding-through vias 115, 116, 117, 118, and 119, respectively, and will not be repeated. By surrounding both of the electrical component 112 and the inductor 114, the coupling issue can be further reduced.

The guarding-through vias 115′, 116′, 117′, 118′, and 119′ may be electrically coupled to ground potential, with one side electrically coupled to conductive layers in the semiconductor die 500, and the other side electrically coupled to ground potential of conductive layers of a semiconductor die over the semiconductor die 500. As a result, the guarding-through vias 115′, 116′, 117′, 118′, 119′ can form isolation cages for the electrical component 112 and the inductor 114 to reduce coupling issue.

FIG. 9 is a perspective view of a semiconductor die 600 in accordance with some embodiments of the present disclosure. It should be noted that the semiconductor die 600 may include the same or similar components as those of the semiconductor die 500, which is illustrated in FIG. 8, and for the sake of simplicity, those components will not be discussed in detail again. In the following embodiments, the guarding-through vias partially surround both of the electrical component 112 and the inductor 114.

As illustrated in FIG. 9, the semiconductor die 600 includes guarding-through vias 118′ and 116 between the electrical component 112 and the inductor 114, in accordance with some embodiments. The guarding-through vias 118′ may be lined up on a side of the electrical component 112 close to the inductor 114, and the guarding-through vias 116 may be lined up on a side of the inductor 114 close to the electrical component 112. The number of the guarding-through vias is reduced to simplify manufacturing processes and reduce costs.

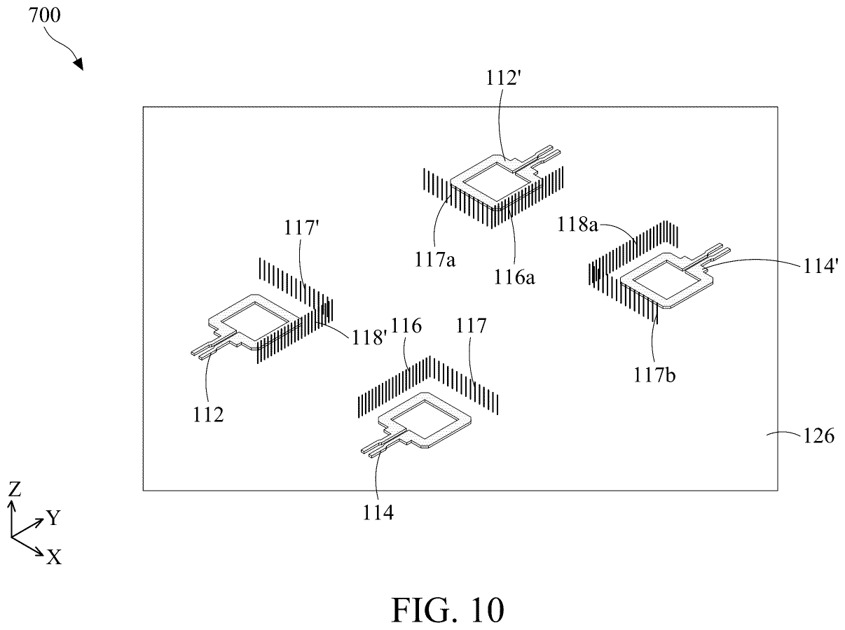

FIG. 10 is a perspective view of a semiconductor die 700 in accordance with some embodiments of the present disclosure. It should be noted that the semiconductor die 700 may include the same or similar components as those of the semiconductor die 500, which is illustrated in FIG. 8, and for the sake of simplicity, those components will not be discussed in detail again. In the following embodiments, more than two inductors are disposed over the dielectric layer 126.

As illustrated in FIG. 10, the semiconductor die 700 includes the electrical component 112, 112′, the inductor 114, and 114′ arranged over the dielectric layer 126, in accordance with some embodiments. The guarding-through vias 118′ may be lined up on a side of the electrical component 112 close to the inductor 114, and the guarding-through vias 117′ may be lined up on a side of the electrical component 112 close to the inductor 112′. The guarding-through vias 118′ and the guarding-through vias 117′ may form an L-shape.

Similarly, the guarding-through vias 116 may be lined up on a side of the inductor 114 close to the electrical component 112, and the guarding-through vias 117 may be lined up on a side of the inductor 114 close to the inductor 114′. The guarding-through vias 116 and the guarding-through vias 117 may form an L-shape. The guarding-through vias 117a may be lined up on a side of the electrical component 112′ close to the electrical component 112, and the guarding-through vias 116a may be lined up on a side of the electrical component 112′ close to the inductor 114′. The guarding-through vias 117a and the guarding-through vias 116a may form an L-shape. The guarding-through vias 118a may be lined up on a side of the inductor 114′ close to the electrical component 112′, and the guarding-through vias 117b may be lined up on a side of the inductor 114′ close to the inductor 114. The guarding-through vias 118a and the guarding-through vias 117b may form an L-shape.

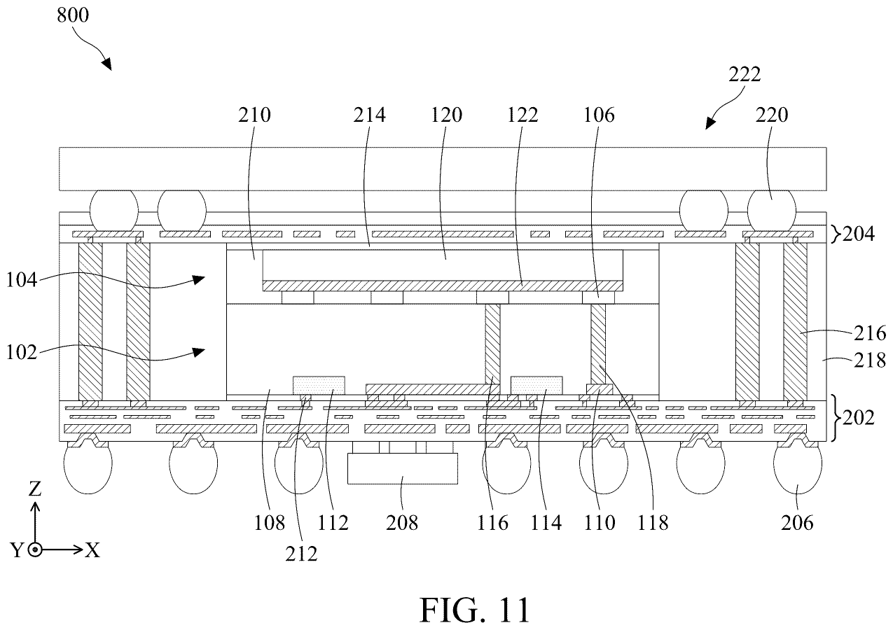

FIG. 11 is a cross-sectional view of a semiconductor package structure 800 in accordance with some embodiments of the present disclosure. It should be noted that the semiconductor package structure 800 may include the same or similar components as those of the semiconductor package structure 100, which is illustrated in FIG. 1, and for the sake of simplicity, those components will not be discussed in detail again.

As illustrated in FIG. 11, the semiconductor package structure 800 includes a first redistribution layer 202, in accordance with some embodiments. The first redistribution layer 202 may include conductive layers disposed in passivation layers. The conductive layers may be formed of conductive materials, including metal (e.g., tungsten, titanium, tantalum, ruthenium, cobalt, copper, aluminum, platinum, tin, silver, gold), metallic compound (e.g., tantalum nitride, titanium nitride, tungsten nitride), the like, an alloy thereof, or a combination thereof. The passivation layers may include polymer layers, which may be formed of polyimide (PI), polybenzoxazole (PBO), benzocyclobutene (BCB), epoxy, the like, or a combination thereof. Alternatively, the passivation layers may include dielectric layers, which may be formed of silicon oxide, silicon nitride, silicon oxynitride, the like, or a combination thereof.

A plurality of conductive terminals 206 are disposed below the first redistribution layer 202, in accordance with some embodiments. The conductive terminals 206 may include microbumps, controlled collapse chip connection (C4) bumps, solder balls, ball grid array (BGA) balls, the like, or a combination thereof. The conductive terminals 206 may be formed of conductive materials, including metal (e.g., tungsten, titanium, tantalum, ruthenium, cobalt, copper, aluminum, platinum, tin, silver, gold), metallic compound (e.g., tantalum nitride, titanium nitride, tungsten nitride), the like, an alloy thereof, or a combination thereof.

The semiconductor package structure 800 includes one or more semiconductor components 208 disposed below the first redistribution layer 202, in accordance with some embodiments. The semiconductor components 208 may include a semiconductor die, an integrated passive device (IPD), any suitable components, or a combination thereof. The semiconductor components 208 may be disposed between the conductive terminals 206 and may be electrically coupled to the first redistribution layer 202.

The semiconductor package structure 800 may include stacked semiconductor dies, including a first semiconductor die 102 and a second semiconductor die 104, disposed over the first redistribution layer 202, in accordance with some embodiments. The second semiconductor die 104 may at least cover an area between the electrical component 112 and the inductor 114. In particular, a projection of the second semiconductor die 104 on a bottom surface of the first semiconductor die 102 may be between the electrical component 112 and the inductor 114.

Although two guarding-through vias 116 and 118 are illustrated in FIG. 11, it should be noted that more or less guarding-through vias can be disposed in the first semiconductor die 102, as described previously. In addition, two semiconductor dies 102 and 104 are for illustrative purposes only, the semiconductor package structure 800 may include more than two semiconductor dies. Furthermore, the semiconductor package structure 800 may also include one or more passive components, such as resistors, capacitors, or inductors.

The first semiconductor die 102 and the second semiconductor die 104 may be electrically coupled to the first redistribution layer 202 through a plurality of conductive structures 212. The conductive structures 212 may be disposed between the first redistribution layer 202 and the first semiconductor die 102. The conductive structures 212 may be formed of conductive materials, such as metal. The conductive structures 212 may include conductive pillars, microbumps, controlled collapse chip connection (C4) bumps, solder balls, ball grid array (BGA) balls, the like, or a combination thereof.

The second semiconductor die 104 and the conductive connectors 106 may be surrounded by a molding material 210. The molding material 210 may cover the top surface of the first semiconductor die 102. The molding material 210 may be formed of a non-conductive material, including moldable polymer, epoxy, resin, the like, or a combination thereof. The sidewalls of the molding material 210 may be substantially aligned with the sidewalls of the first semiconductor die 102. The top surface of the molding material 210 may be substantially aligned with the top surface of the second semiconductor die 104.

In some embodiments, an adhesion layer 214 is disposed over the second semiconductor die 104 and the molding material 210. The adhesion layer 214 may include a die attach film (DAF), an epoxy, the like, or a combination thereof. The adhesion layer 214 is optional. In some other embodiments, the adhesion layer 214 is not adopted.

A plurality of conductive pillars 216 are disposed over the first redistribution layer 202, in accordance with some embodiments. The conductive pillars 216 may be adjacent to the first semiconductor die 102 and the second semiconductor die 104. The conductive pillars 216 may be formed of metal, such as copper, tungsten, the like, or a combination thereof. In some embodiments, the conductive pillars 216 are formed by a plating process or any other suitable process. The thickness of the conductive pillars 216 in the direction substantially vertical to the top surface of the first redistribution layer 202 may be greater than the thickness of the guarding-through vias 116 and 118.

A molding material 218 may surround each of the conductive pillars 216, the molding material 210, the first semiconductor die 102, the conductive structures 212, and the adhesion layer 214 (if present). The molding material 218 may protect these components from the environment, thereby protecting them from damage due to stress, chemicals, and moisture. The molding material 218 may be formed of a non-conductive material, including moldable polymer, epoxy, resin, the like, or a combination thereof. The sidewalls of the molding material 218 may be substantially aligned with the sidewalls of the first redistribution layer 202.

A second redistribution layer 204 is disposed over the first redistribution layer 202, in accordance with some embodiments. The second redistribution layer 204 may be electrically coupled to the first redistribution layer 202 through the conductive pillars 218. The second redistribution layer 204 may be similar to the first redistribution layer 202, and will not be repeated. However, the numbers of the conductive layers and the passivation layers of the first redistribution layer 202 may be different than those of the second redistribution layer 204. The sidewalls of the second redistribution layer 204 may be substantially aligned with the sidewalls of the molding material 218.

A package structure 222 is disposed over the second redistribution layer 204, in accordance with some embodiments. The package structure 222 may include a package substrate. The package substrate may have routing layers therein. In some embodiments, the routing layers of the package substrate includes conductive layers, conductive vias, conductive pillars, the like, or a combination thereof. The routing layers of the package substrate may be formed of conductive materials, including metal (e.g., tungsten, titanium, tantalum, ruthenium, cobalt, copper, aluminum, platinum, tin, silver, gold), metallic compound (e.g., tantalum nitride, titanium nitride, tungsten nitride), the like, an alloy thereof, or a combination thereof.

The routing layers of the package substrate may be disposed in inter-metal dielectric (IMD) layers. In some embodiments, the IMD layers may be formed of organic materials, such as a polymer base material, a non-organic material, such as silicon nitride, silicon oxide, silicon oxynitride, the like, or a combination thereof.

A plurality of conductive terminals 220 are disposed below the package structure 222 and electrically coupled to the second redistribution layer 204, in accordance with some embodiments. The conductive terminals 220 may include microbumps, controlled collapse chip connection (C4) bumps, solder balls, ball grid array (BGA) balls, the like, or a combination thereof. The conductive terminals 220 may be formed of conductive materials, including metal (e.g., tungsten, titanium, tantalum, ruthenium, cobalt, copper, aluminum, platinum, tin, silver, gold), metallic compound (e.g., tantalum nitride, titanium nitride, tungsten nitride), the like, an alloy thereof, or a combination thereof.

The package structure 222 includes one or more semiconductor dies disposed over the package substrate, in accordance with some embodiments. The semiconductor dies may include the devices similar to those discussed with respect to the first semiconductor die 102 and the second semiconductor die 104. For example, the semiconductor dies in the package structure 222 may include memory dies, such as a dynamic random access memory (DRAM), or another suitable device. The semiconductor dies may be electrically coupled to the package substrate. The package structure 222 may also include one or more passive components, including resistors, capacitors, inductors, or a combination thereof.

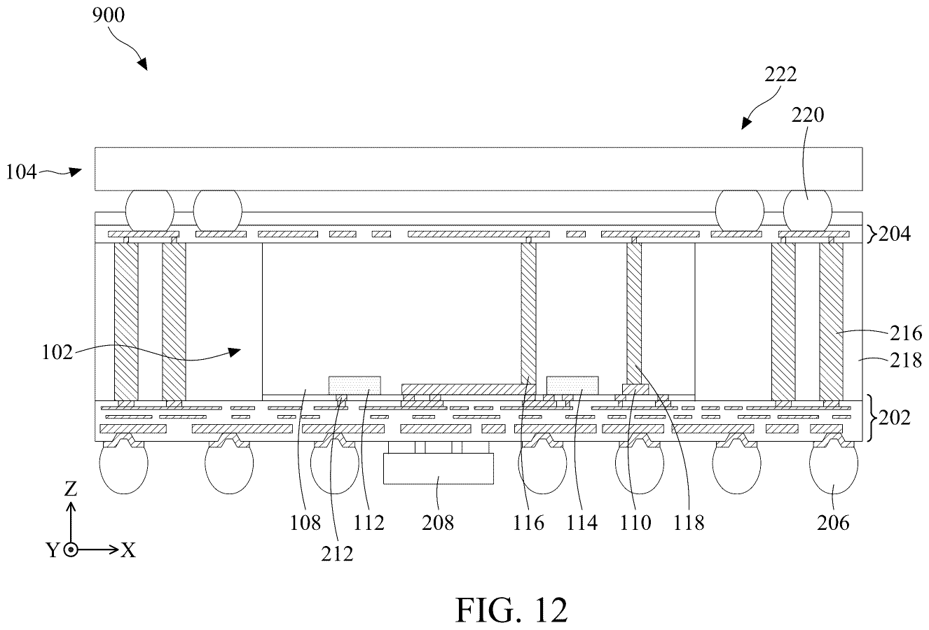

FIG. 12 is a cross-sectional view of a semiconductor package structure 900 in accordance with some embodiments of the present disclosure. It should be noted that the semiconductor package structure 900 may include the same or similar components as those of the semiconductor package structure 800, which is illustrated in FIG. 11, and for the sake of simplicity, those components will not be discussed in detail again. In the following embodiments, the first semiconductor die and the second semiconductor die are disposed on opposite surfaces of the second redistribution layer.

As illustrated in FIG. 12, the first semiconductor die 102 may be disposed between the first redistribution layer 202 and the second redistribution layer 204. The second semiconductor die 104 may be disposed over the second redistribution layer 204. The package structure 222 may include the second semiconductor die 104. The conductive layers in the second redistribution layer 204 and the conductive layers 110 in the first semiconductor die 102 may form a coupling path, which causes coupling issue with the electrical component 112 and the inductor 114 in the first semiconductor die 102.

The guarding-through vias 116 and 118 may be electrically coupled to ground potential, with one side electrically coupled to the conductive layers 110 in the first semiconductor die 102, and the other side electrically coupled to ground potential of the second redistribution layer 204 sandwiched between the first semiconductor die 102 and the second semiconductor die 104 to alleviate this issue.

The top surface of the first semiconductor die 102 may be in contact with the bottom surface of the second redistribution layer 204. The thickness of the conductive pillars 216 in the direction substantially vertical to the top surface of the first redistribution layer 202 may be greater than the thickness of the guarding-through vias 116 and 118.

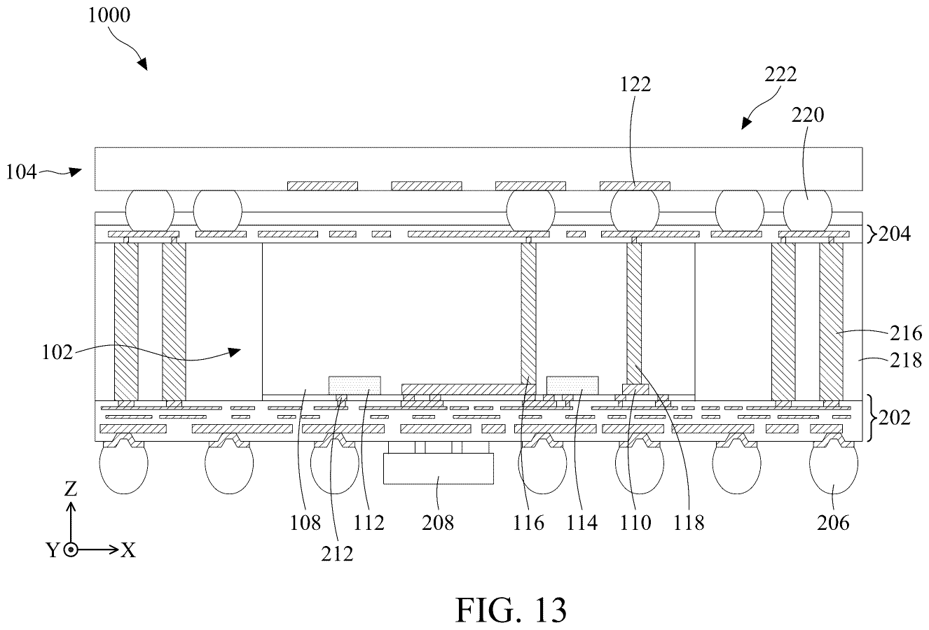

FIG. 13 is a cross-sectional view of a semiconductor package structure 1000 in accordance with some embodiments of the present disclosure. It should be noted that the semiconductor package structure 1000 may include the same or similar components as those of the semiconductor package structure 900, which is illustrated in FIG. 12, and for the sake of simplicity, those components will not be discussed in detail again. In the following embodiments, the first semiconductor die 102 and the second semiconductor die 104 are disposed on opposite surfaces of the second redistribution layer 204. The conductive layers 122 in the second semiconductor die 104 and the conductive layers 110 in the first semiconductor die 102 may form a coupling path, which causes coupling issue with the electrical component 112 and the inductor 114 in the first semiconductor die 102.

As shown in FIG. 13, the guarding-through vias 116 and 118 may be electrically coupled to ground potential, with one side electrically coupled to the conductive layers 110 in the first semiconductor die 102, and the other side electrically coupled to ground potential of the conductive layers 122 of the second semiconductor die 104 through the conductive terminals 220 and the second redistribution layer 204 to alleviate the coupling issue.

Although two guarding-through vias 116 and 118 are illustrated in FIGS. 12 and 13, it should be noted that more or less guarding-through vias can be disposed in the first semiconductor die 102, as described previously.

As described previously, the semiconductor package substrate may include guarding-through vias 116 and 118 to reduce aggressors-to-inductor coupling noise. In the embodiments illustrated in FIG. 2, the second semiconductor die 104 includes the through vias 124 for electrically coupling the guarding-through vias 116 and 118. In the embodiments illustrated in FIG. 6, more circles of guarding-through vias 115, 116, 117, 118, 119 surround one of the inductors 112 and 114 to further reduce the coupling issue. In the embodiments illustrated in FIG. 7, the guarding-through vias 115, 116, 117, 118, 119 of different circles are in a staggered arrangement to further reduce the coupling issue. In the embodiments illustrated in FIG. 8, the guarding-through vias 115, 115′, 116, 116′, 117, 117′, 118, 118′, 119, 119′ surround both of the inductors 112 and 114. In the embodiments illustrated in FIG. 9, the guarding-through vias 118′ and 116 are arranged between the electrical component 112 and the inductor 114. In the embodiments illustrated in FIG. 10, the guarding-through vias around each of the inductors 112, 112, 114, and 114′ form an L shape. In the embodiments illustrated in FIG. 11, the first semiconductor die 102 and the second semiconductor die 104 are surrounded by the molding material 218. In the embodiments illustrated in FIGS. 12 and 13, the first semiconductor die 102 and the second semiconductor die 104 are separated by the second redistribution layer 204.

In summary, the semiconductor package structure according to the present disclosure includes guarding-through vias in the lower one of stacked semiconductor dies. The guarding-through vias may be disposed between two inductors to reduce aggressors-to-inductor coupling noise caused by the upper one of stacked semiconductor dies. According to some embodiments, the number and the arrangement of the guarding-through vias may be adjusted to further reduce the coupling issue or simplify manufacturing process.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package structure, comprising:
a first semiconductor die, comprising:
an electrical component and an inductor disposed in a dielectric layer;
a semiconductor substrate disposed over the dielectric layer; and
a first row of guarding-through vias extending through the semiconductor substrate and between the electrical component and the inductor;
a second semiconductor die vertically overlapping the first row of through vias; and
a conductive structure disposed over the first semiconductor die and electrically coupling the second semiconductor die to the first row of guarding-through vias.

2. The semiconductor package structure as claimed in claim 1, further comprising:
a grounding layer disposed in the dielectric layer and electrically coupled to the first row of guarding-through vias.

3. The semiconductor package structure as claimed in claim 1, wherein the first row of guarding-through vias are arranged along a first sidewall of the inductor, and the first semiconductor die further comprises:
a second row of guarding-through vias arranged along a second sidewall of the inductor;
a third row of guarding-through vias arranged along a third sidewall of the inductor; and
a fourth row of guarding-through vias and a fifth row of guarding-through vias arranged along a fourth sidewall of the inductor.

4. The semiconductor package structure as claimed in claim 3, wherein the fourth row of guarding-through vias and the fifth row of guarding-through vias are spaced apart by a first distance greater than a second distance between two of the guarding-through vias.

5. The semiconductor package structure as claimed in claim 1, wherein the first row of guarding-through vias are arranged along a sidewall of the inductor, and the first semiconductor die further comprises:
a second row of guarding-through vias arranged along a sidewall of the electrical component and between the electrical component and the inductor.

6. The semiconductor package structure as claimed in claim 1, wherein a thickness of the first semiconductor die is substantially equal to or larger than 10 μm.

7. The semiconductor package structure as claimed in claim 1, wherein the conductive structure comprises a plurality of bump structures between the first semiconductor die and the second semiconductor die.

8. The semiconductor package structure as claimed in claim 7, further comprising:
a molding material over the first semiconductor die and surrounding the second semiconductor die and the bump structures.

9. The semiconductor package structure as claimed in claim 1, wherein the conductive structure comprises a redistribution layer between the first semiconductor die and the second semiconductor die, and the redistribution layer extends beyond sidewalls of the first semiconductor die.

10. The semiconductor package structure as claimed in claim 1, wherein the conductive structure comprises through vias in the second semiconductor die.

11. A semiconductor package structure, comprising:
a first semiconductor die, comprising:
an electrical component and an inductor disposed on a frontside of the first semiconductor die;
a conductive layer between the electrical component and the inductor; and
a plurality of guarding-through vias extending from a backside of the first semiconductor die to the conductive layer and arranged along a first sidewall of the inductor; and
a second semiconductor die disposed over the backside of the first semiconductor die and electrically coupled to the guarding-through vias.

12. The semiconductor package structure as claimed in claim 11, wherein the conductive layer is electrically coupled to ground.

13. The semiconductor package structure as claimed in claim 11, further comprising:
a plurality of bump structures on the backside of the first semiconductor die and electrically coupled to the guarding-through vias.

14. The semiconductor package structure as claimed in claim 13, further comprising:
a molding material surrounding the first semiconductor die and the second semiconductor die; and
a conductive pillar extending through the molding material,
wherein a thickness of the conductive pillar is greater than a thickness of the guarding-through vias.

15. The semiconductor package structure as claimed in claim 11, wherein the guarding-through vias surround the inductor.

16. The semiconductor package structure as claimed in claim 11, wherein the distance between the inductor and the guarding-through vias is less than a distance between the electrical component and the guarding-through vias.

17. The semiconductor package structure as claimed in claim 11, further comprising:
a molding material surrounding the first semiconductor die; and
a redistribution layer covering the molding material,
wherein the second semiconductor die is disposed over the redistribution layer.

18. A semiconductor package structure, comprising:
a first semiconductor die, comprising:
an electrical component;
an inductor adjacent to the first electrical component; and
a plurality of first guarding-through vias surrounding the electrical component, wherein a first side of the first guarding-through vias is electrically coupled to a ground; and
a second semiconductor die disposed over the first semiconductor die and comprising a conductive layer, wherein the conductive layer is electrically coupled to a second side of the first guarding-through vias.

19. The semiconductor package structure as claimed in claim 18, further comprising:
a plurality of second guarding-through vias surrounding the first guarding-through vias.

20. The semiconductor package structure as claimed in claim 18, further comprising:
a plurality of second guarding-through vias surrounding the inductor.
